(19) United States
(12) Patent Application Publication
(10) Pub. No.: US 2014/0109934 A1
(43) Pub. Date: Apr. 24, 2014

(54) APPARATUS FOR REMOVING PARTICLES FROM PRINTED CIRCUIT BOARD AND METHOD FOR REMOVING PARTICLES FROM PRINTED CIRCUIT BOARD

(71) Applicant: SAMSUNG ELECTRO-MECHANICS CO., LTD., Suwon-si (KR)

(72) Inventor: Young Kwan LEE, Suwon-si (KR)

(73) Assignee: SAMSUNG ELECTRO-MECHANICS CO., LTD., Suwon-si (KR)

(21) Appl. No.: 13/844,094

(22) Filed: Mar. 15, 2013

(30) Foreign Application Priority Data
Oct. 18, 2012 (KR) 10-2012-0115911

(51) Int. Cl. H05K 3/26; B08B 7/02; B08B 5/04

(52) U.S. Cl. CPC H05K 3/26; B08B 5/04; B08B 7/02
USPC 134/18; 15/303

(57) ABSTRACT

Disclosed herein are an apparatus for removing particles from a printed circuit board and a method for removing particles from a printed circuit board. The apparatus includes: a vibration generating unit vibrating a printed circuit board; a vacuum sucking unit formed over the printed circuit board and removing the particles from the printed circuit board; and a controlling unit controlling the vibration generating unit and the vacuum sucking unit.

### CROSS REFERENCE(S) TO RELATED APPLICATIONS

This application claims the benefit under 35 U.S.C. Section 119 of Korean Patent Application Serial No. 10-2012-0115911, entitled “Apparatus for Removing Particles from Printed Circuit Board and Method for Removing Particles from Printed Circuit Board” filed on Oct. 18, 2012, which is hereby incorporated by reference in its entirety into this application.

### BACKGROUND OF THE INVENTION

1. Technical Field

The present invention relates to an apparatus for removing particles from a printed circuit board and a method for removing particles from a printed circuit board, and more particularly, to an apparatus for removing particles from a printed circuit board and a method for removing particles from a printed circuit board capable of removing the particles without contacting the printed circuit board.

2. Description of the Related Art

In general, a printed circuit board (PCB), which is a circuit board serving to electrically connect or mechanically fix a predetermined electronic element, has a predetermined circuit pattern formed thereon by coating an insulating plate formed of an insulating material such as a phenol resin or an epoxy resin with a copper foil and selectively removing the copper foil.

Here, the printed circuit board is classified into a single PCB in which the circuit pattern is only formed on one surface of the insulating plate, a double PCB in which the circuit pattern is formed on both surfaces of the insulating plate, and a multi layer PCB in which the insulating plates having the circuit pattern formed thereon are stacked to allow the circuit pattern to be formed as a multi-layer.

The printed circuit board as described above is manufactured by sequentially performing multi-stage processes, such as an exposure process, a development process, a washing process, an etching process, a peeling process and a drying process.

During the process of manufacturing the printed circuit board, several defects occur, wherein a particle defect in which particles are attached to a surface of the printed circuit board is the biggest in the defects of the printed circuit board.

Particularly, in accordance with the trend toward slimness and lightness of electronic products according to miniaturization, thinning, high densification, packaging, and portability thereof, the printed circuit board has also been required for multi-layering in which a plurality of circuit layers are formed and micro-patterning in which the circuit pattern is microfined. Therefore, light characteristics is disturbed due to particles during the exposure process, which causes a circuit defect such as disconnection or a leak defect, thereby generating a problem in production.

Therefore, it is an important technical challenge to remove the above-mentioned particles on the printed circuit board and the particles are removed using a particle removing apparatus for removing the above-mentioned particles on the spot.

The apparatus for removing the particles from the printed circuit board according to the related art has removed the particles on a surface of the printed circuit board using a clean roller having an adhesive tape formed thereon.

However, the apparatus for removing the particles using the clean roller has generated a difference in removing the particles from the surface of the printed circuit board due to a pressure difference according to an area in which the clean roller contacts, has damaged the surface of the printed circuit board such as scratch in the case of a metallic particle, and has generated a reverse effect that the particles which has adhered to the clean roller is transferred to the printed circuit board to cause defects such as particles and contamination resulted thereby.

### SUMMARY OF THE INVENTION

An object of the present invention is to provide an apparatus for removing particles from a printed circuit board and a method for removing particles from a printed circuit board capable of preventing damage to a printed circuit board and a secondary contamination due to a transfer of the particles and effectively removing the particle.

According to an exemplary embodiment of the present invention, there is provided an apparatus for removing particles from a printed circuit board, the apparatus including: a vibration generating unit vibrating a printed circuit board; a vacuum sucking unit formed over the printed circuit board and removing the particles from the printed circuit board; and a controlling unit controlling the vibration generating unit and the vacuum sucking unit.

The apparatus may further include a photographing unit formed over the printed circuit board and photographing the printed circuit board.

The controlling unit may be connected to the photographing unit and may move the vacuum sucking unit so as to suck the particles when a position of the particles is determined from an image photographed by the photographing unit.

The vibration generating unit may aggregate the particles on the printed circuit board at a predetermined position.

The vibration generating unit may be formed of an acoustic device.

The vibration generating unit may be formed so as to contact the printed circuit board and may vibrate the printed circuit board.

The vacuum sucking unit may be movably formed over the printed circuit board.

The vacuum sucking unit may be formed so as to be fixed at a predetermined position over the printed circuit board.

A plurality vacuum sucking units may be formed over the printed circuit board.

The controlling unit may include: a signal generating unit generating a frequency signal inducing a natural frequency of the printed circuit board; and a signal amplifying unit amplifying the frequency signal generated from the signal generating unit and transmitting the amplified frequency signal to the vibration generating unit.

According to another exemplary embodiment of the present invention, there is provided a method for removing particles from a printed circuit board using an apparatus for removing the particles from the printed circuit board including a vibration generating unit, a vacuum sucking unit, a controlling unit, and a photographing unit, the method including: checking a frequency signal inducing natural frequency of the printed circuit board; generating, by the controlling unit, the checked frequency signal; vibrating, by the vibration generating unit, the printed circuit board using the frequency signal generated from the controlling unit; and removing, by the vacuum sucking unit, particles on the vibrated printed circuit board.

The controlling unit may be configured of a signal generating unit and a signal amplifying unit, and the generating of the checked frequency signal may include: generating, by the signal generating unit, the frequency signal; and amplifying, by the signal amplifying unit, the generated frequency signal and transmitting the amplified frequency signal to the vibration generating unit.

In the vibrating of the printed circuit board, the printed circuit board may naturally vibrate and the particles on the printed circuit board may be aggregated at a predetermined position according to the natural vibration of the printed circuit board.

The removing of the particles may include: photographing an upper surface of the vibrated printed circuit board using the photographing unit; and moving the vacuum sucking unit to a position in which the particles are aggregated based on the photographed image and removing the particles.

### BRIEF DESCRIPTION OF THE DRAWINGS

FIG. 1 is a schematic view showing an apparatus for removing particles from a printed circuit board according to an exemplary embodiment of the present invention;

FIG. 2 is a configuration view showing the apparatus for removing particles from a printed circuit board according to the exemplary embodiment of the present invention;

FIG. 3 is a schematic view showing an apparatus for removing particles from a printed circuit board according to another exemplary embodiment of the present invention; and

FIG. 4 is a flow chart showing a method for removing particles from a printed circuit board according to an exemplary embodiment of the present invention.

### DESCRIPTION OF THE PREFERRED EMBODIMENTS

Hereinafter, exemplary embodiments of the present invention will be described with reference to the accompanying drawings. However, the exemplary embodiments are described by way of examples only and the present invention is not limited thereto.

In describing the present invention, when a detailed description of well-known technology relating to the present invention may unnecessarily make unclear the spirit of the present invention, a detailed description thereof will be omitted. Further, the following terminologies are defined in consideration of the functions in the present invention and may be construed in different ways by the intention of users and operators. Therefore, the definitions thereof should be construed based on the contents throughout the specification.

As a result, the spirit of the present invention is determined by the claims and the following exemplary embodiments may be provided to efficiently describe the spirit of the present invention to those skilled in the art.

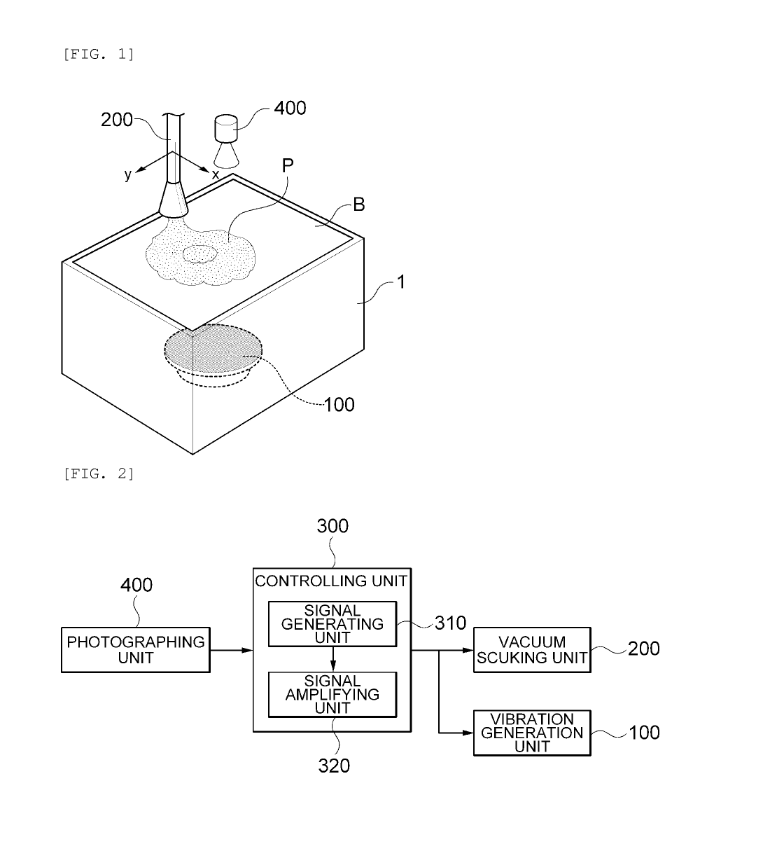

FIG. 1 is a schematic view showing an apparatus for removing particles from a printed circuit board according to an exemplary embodiment of the present invention and FIG. 2 is a configuration view showing the apparatus for removing particles from a printed circuit board according to the exemplary embodiment of the present invention.

As shown in FIGS. 1 and 2, the apparatus for removing the particles from the printed circuit board according to the exemplary embodiment of the present invention includes a vibration generating unit 100 vibrating a printed circuit board B, a vacuum sucking unit 200 which is formed over the printed circuit board B and removes the particles from the printed circuit board B, and a controlling unit 300 controlling the vibration generating unit 100 and the vacuum sucking unit 200.

In addition, the apparatus for removing particles from a printed circuit board according to the exemplary embodiment of the present invention further includes a photographing unit 400 formed over the printed circuit board B to photograph the printed circuit board B.

The vibration generating unit 100 generating vibration may vibrate the printed circuit board B by delivering vibration to the printed circuit board B.

Here, the vibration generating unit 100 may be formed of an acoustic device generating acoustic energy. For example, the vibration generating unit 100 may be formed of a speaker.

In this case, the vibration generating unit 100 generates the acoustic energy at an audible sound (20 Hz˜20 kHz) corresponding to the natural frequency of the printed circuit board B and the generated acoustic energy is delivered to the printed circuit board B to allow the printed circuit board B to induce the natural frequency.

Then, the printed circuit board B vibrates in a natural mode corresponding to the natural frequency, such that particles P attached to a surface of the printed circuit board B are aggregated at a predetermined position, as the printed circuit board B vibrates in the natural mode.

In this case, the particles P may be aggregated in a predetermined pattern shape according to the natural mode.

In addition, the vibration generating unit 100 may be formed below the printed circuit board B so as to be spaced apart from the printed circuit board B at a predetermined interval and may be formed in a box shaped chamber 1 capable of blocking sound waves so that the sound wave may be prevented from being echoed and may be concentratedly delivered to the printed circuit board B.

Moreover, the vibration generating unit 100 may be formed over the printed circuit board B so as to be spaced apart from each other at a predetermined interval to thereby face the printed circuit board B. Here, the vibration generating unit 100 may be formed at one side of the vacuum sucking unit 200 to be described below.

Meanwhile, although the case in which the vibration generating unit 100 vibrates the printed circuit board B through acoustic energy generated since it is spaced from the printed circuit board B has been described in the exemplary embodiment of the present invention, the vibration generating unit 100 may be formed so as to directly contact one side of the printed circuit board B to thereby generate the vibration corresponding to the natural frequency of the printed circuit board B. Here, the vibration generating unit 100 may be formed of a vibration motor or the like.

In addition, the vibration generating unit 100 is not limited thereto, but may be formed of any configuration, if configuration thereof may vibrate the printed circuit board B in the natural mode.

The vacuum sucking unit 200, which removes the particles from the printed circuit board B, may be formed over the printed circuit board B and may be formed of a device capable of sucking the particles P, such as a suction fan, a ring blower, a vacuum suction equipment or the like.

Here, one vacuum sucking unit 200 may be formed over the printed circuit board B and a plurality of vacuum sucking units 200 may also be formed over the printed circuit board B according to a selection of a designer.

Further, the vacuum sucking unit 200 may be formed so as to move in an X axis direction and a Y axis direction.

That is, the vacuum sucking unit 200 may vibrate in the natural mode and move over the particles P which are aggregated at a predetermined position to vacuum-suck the particles P, thereby removing the particles without contacting the printed circuit board B. Therefore, since the consumption parts such as an adhesive tape, which is a method for removing the particles according to the related art, are not used, cost may be reduced, damage to the printed circuit board and induction of the particles due to friction between the printed circuit board B and the adhesive tape may be prevented, and a secondary contamination due to a transfer of the particles may be prevented.

The controlling unit 300 may control driving of the vibration generating unit 100 and the vacuum sucking unit 200.

The controlling unit 300 may control a vibration generation of the vibration generating unit 100 and may be configured of a signal generating unit 310 and a signal amplifying unit 320.

In this configuration, the signal generating unit 310 may generate a frequency signal having a band in which the natural frequency of the printed circuit board B is induced and the signal amplifying unit 320 may amplify the frequency signal generated from the signal generating unit 310 and transmit the amplified frequency signal to the vibration generating unit 100, thereby allowing the vibration generating unit 100 to generate the acoustic energy corresponding to the natural frequency of the printed circuit board B.

In addition, the controlling unit 300 may control a driving of vacuum suction of the vacuum sucking unit 200 and a movement of the vacuum sucking unit 200.

The controlling unit 300 may store, in advance, information on the position in which the particles P are aggregated on the printed circuit board B and control the movement of the vacuum sucking unit 200 based on the information on the position in which the particles P are aggregated, stored in the controlling unit 300, thereby allowing the particles P to be removed.

Meanwhile, the photographing unit 400 may be connected to the controlling unit 300.

Here, the photographing unit 400, which photographs an upper surface of the printed circuit board B, may be formed at one side of the vacuum sucking unit 200.

In addition, the photographing unit 400 may photograph the upper surface of the printed circuit board B and determine the position of the particles P aggregated in a pattern shape from the photographed image, thereby transmitting the determined position of the particles P to the controlling unit 300.

That is, in the case in which the photographing unit 400 is formed, the controlling unit 300 controls the vacuum sucking unit 200 based on the position of the particles P determined by the photographing unit 400, such that the vacuum sucking unit 200 may be moved to the position in which the particles P are aggregated to suck the particles P, thereby removing the particles P.

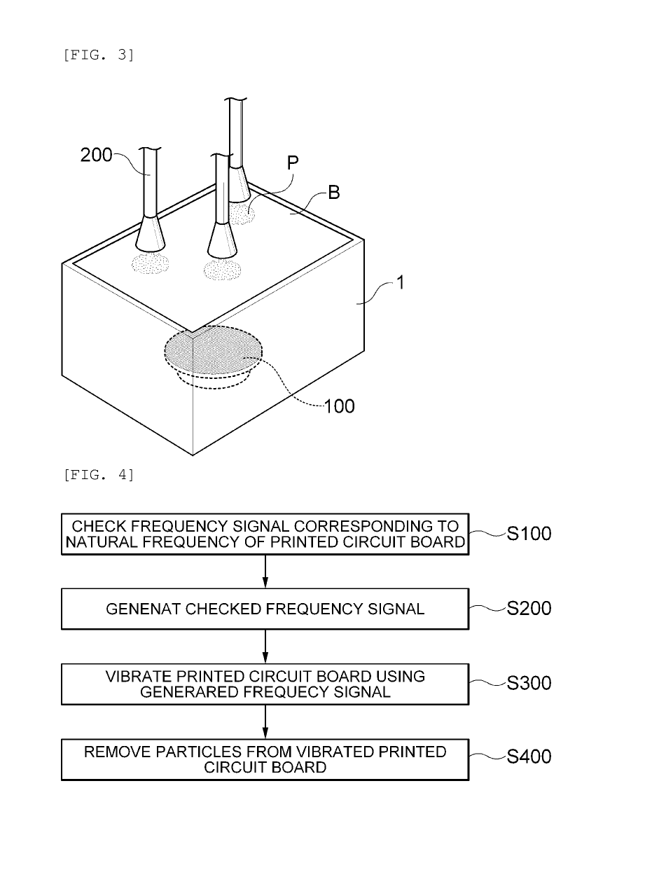

Although the vacuum sucking unit 200 which is movably formed is described as an example in the apparatus for removing particles from a printed circuit board according to the exemplary embodiment of the present invention, the vacuum sucking unit 200 may be formed so as to be fixed over the printed circuit board B as shown in FIG. 3.

Here, a plurality of vacuum sucking units 200 may be formed.

In this configuration, the vibration generating unit 100 may vibrate the printed circuit board B in the natural mode so as to aggregate the particles P of the printed circuit board B to the position in which the vacuum sucking unit 200 is formed.

That is, the vibration generating unit 100 aggregates the particles P on the printed circuit board B to the position in which the vacuum sucking unit 200 is formed and the vacuum sucking unit 200 sucks the aggregated particles P, thereby making it possible to remove the particles P from the printed circuit board B.

Hereinafter, a method for removing particles from a printed circuit board using an apparatus for removing particles from a printed circuit board according to the exemplary embodiment of the present invention will be described with reference to FIG. 4.

FIG. 4 is a flow chart showing a method for removing particles from a printed circuit board according to an exemplary embodiment of the present invention.

As shown in FIG. 4, the method for removing particles from a printed circuit board according to the exemplary embodiment of the present invention uses the apparatus for removing particles from a printed circuit board described in the previous embodiment and includes checking a frequency signal inducing a natural frequency of the printed circuit board (S100), generating, by the controlling unit, the checked frequency signal (S200), vibrating, by the vibration generating unit, the printed circuit board using the frequency signal generated by the controlling unit (S300), and removing, by the vacuum sucking unit, particles from the vibrated printed circuit board (S400).

First, the checking of the frequency signal inducing the natural frequency of the printed circuit board B may be performed (S100).

Here, since the natural frequency is varied according to strenth of the printed circuit board B, the natural frequency for the printed circuit board B in which the particles P are to be removed is checked.

In this case, in the checking of the frequency signal inducing the natural frequency of the printed circuit board B, the natural frequency of the printed circuit board B is checked by analyzing a response signal for vibration of the printed circuit board B using a vibration sensor of an accelerator or a displacement meter and an impact hammer.

In addition, the frequency signal checked as one generating the natural frequency of the printed circuit board B is stored in the controlling unit 300.

Next, the generating, by the controlling unit 300, of the checked frequency signal may be performed (S200).

Here, the controlling unit 300 may be configured of a signal generating unit 310 and a signal amplifying unit 320.

First, the signal generating unit 310 generates the checked frequency signal and the signal amplifying unit 320 amplifies the generated frequency signal to transmit the amplified frequency signal to the vibration generating unit 100.

Next, the vibrating, by the vibration generating unit, of the printed circuit board using the frequency signal generated by the controlling unit may be performed (S300).

Here, the frequency signal generated from the controlling unit 300 is transmitted to the vibration generating unit 100, the vibration generating unit 100 generates the acoustic energy of audible sound (20 Hz˜20 kHz) corresponding to the natural frequency of the printed circuit board B according to the received frequency signal, and the generated acoustic energy is delivered to the printed circuit board B to allow the printed circuit board B to induce the natural frequency of the printed circuit board B.

Then, the printed circuit board B vibrates in a natural mode corresponding to the natural frequency, such that particles P attached to a surface of the printed circuit board B are aggregated at a predetermined position as the printed circuit board B vibrates in the natural mode.

Next, the removing, by the vacuum sucking unit 200, of the particles from the vibrated printed circuit board B may be performed (S400).

Here, the printed circuit board B in which the particles P are aggregated at a predetermined position is photographed by the photographing unit 400 and the position in which the particles P are aggregated is determined from the photographed image.

Then, the vacuum sucking unit 200 is moved to the position in which the particles P are aggregated to suck the particles P, thereby removing the particles P.

Therefore, in the apparatus for removing particles from a printed circuit board and the method for removing particles from a printed circuit board according to the exemplary embodiment of the present invention, the vacuum sucking unit vacuum-sucks the particles to remove the particles from the printed circuit board, such that the consumption part such as the adhesive tape is not used, thereby making it possible to reduce cost. In addition, the vacuum sucking unit vacuum-sucks the particles to remove the particles without contacting the printed circuit board, thereby making it possible to prevent damage to the printed circuit board and the induction of particles due to the friction or impact upon contact and prevent secondary contamination due to the transfer.

In addition, the printed circuit board vibrates in the natural mode using the vibration generating unit, such that the particles which are distributed at unspecified positions may be aggregated at the predetermined position to be removed at one time, thereby making it possible to shorten the time required for removing the particles and effectively remove the particles as in consideration of the energy consumption.

Although the exemplary embodiments of the present invention have been disclosed for illustrative purposes, those skilled in the art will appreciate that various modifications, additions and substitutions are possible, without departing from the scope and spirit of the invention as disclosed in the accompanying claims.

Accordingly, the scope of the present invention is not construed as being limited to the described embodiments but is defined by the appended claims as well as equivalents thereto.

What is claimed is:

1. An apparatus for removing particles from a printed circuit board, the apparatus comprising:
a vibration generating unit vibrating a printed circuit board;
a vacuum sucking unit formed over the printed circuit board and removing the particles from the printed circuit board; and
a controlling unit controlling the vibration generating unit and the vacuum sucking unit.

2. The apparatus according to claim 1, further comprising a photographing unit formed over the printed circuit board and photographing the printed circuit board.

3. The apparatus according to claim 2, wherein the controlling unit is connected to the photographing unit and moves the vacuum sucking unit to the position so as to suck the particles when a position of the particles is determined from an image photographed by the photographing unit.

4. The apparatus according to claim 1, wherein the vibration generating unit aggregates the particles on the printed circuit board at a predetermined position.

5. The apparatus according to claim 1, wherein the vibration generating unit is formed of an acoustic device.

6. The apparatus according to claim 1, wherein the vibration generating unit is formed so as to contact the printed circuit board and vibrates the printed circuit board.

7. The apparatus according to claim 1, wherein the vacuum sucking unit is movably formed over the printed circuit board.

8. The apparatus according to claim 1, wherein the vacuum sucking unit is formed so as to be fixed at a predetermined position over the printed circuit board.

9. The apparatus according to claim 7, wherein a plurality vacuum sucking units are formed over the printed circuit board.

10. The apparatus according to claim 8, wherein a plurality vacuum sucking units are formed over the printed circuit board.

11. The apparatus according to claim 1, wherein the controlling unit includes:
a signal generating unit generating a frequency signal inducing a natural frequency of the printed circuit board; and
a signal amplifying unit amplifying the frequency signal generated from the signal generating unit and transmitting the amplified frequency signal to the vibration generating unit.

12. A method for removing particles from a printed circuit board using an apparatus for removing particles from a printed circuit board including a vibration generating unit, a vacuum sucking unit, a controlling unit, and a photographing unit, the method comprising:
checking a frequency signal inducing a natural frequency of a printed circuit board;
generating, by the controlling unit, the checked frequency signal;
vibrating, by the vibration generating unit, the printed circuit board using the frequency signal generated from the controlling unit; and
removing, by the vacuum sucking unit, particles from the vibrated printed circuit board.

13. The method according to claim 12, wherein the controlling unit is configured of a signal generating unit and a signal amplifying unit, and
the generating of the checked frequency signal includes:
generating, by the signal generating unit, the frequency signal; and
amplifying, by the signal amplifying unit, the generated frequency signal and transmitting the amplified frequency signal to the vibration generating unit.

14. The method according to claim 12, wherein in the vibrating of the printed circuit board, the printed circuit board naturally vibrates and the particles on the printed circuit board are aggregated at a predetermined position according to the natural vibration of the printed circuit board.

15. The method according to claim 12, wherein the removing of the particles includes:
photographing an upper surface of the vibrated printed circuit board using the photographing unit; and
moving the vacuum sucking unit to a position in which the particles are aggregated based on the photographed image and removing the particles.
